(19) United States
(12) Patent Application Publication
(10) Pub. No.: US 2025/0320627 A1
(43) Pub. Date: Oct. 16, 2025

(54) CHAMBER LINERS AND CHAMBER KITS TO REDUCE EDGE ROLL OFF FOR PROCESSING CHAMBERS

(71) Applicant: Applied Materials, Inc., Santa Clara, CA (US)

(72) Inventors: Abraham PALATY, San Jose, CA (US); Youngki CHANG, Santa Clara, CA (US); Shu-Kwan LAU, Sunnyvale, CA (US)

(21) Appl. No.: 19/083,814

(22) Filed: Mar. 19, 2025

Related U.S. Application Data
(60) Provisional application No. 63/634,127, filed on Apr. 15, 2024.

(51) Int. Cl. C30B 25/08; C30B 25/14

(52) U.S. Cl. CPC C30B 25/08; C30B 25/14

(57) ABSTRACT

The present disclosure relates to liners having flow openings, and related chamber kits, processing chambers, and methods for semiconductor manufacturing. In one or more embodiments, a liner for a processing chamber is provided. The liner includes an inner face, an outer face opposing the inner face, a first portion defining at least part of the outer face and the inner face, and a second portion defining at least part of the outer face and the inner face, the second portion opposing the first portion, and the second portion and the first portion having an azimuthal angle greater than 150 degrees. The liner further includes an gas inlet opening extending into the inner face and into the first portion, and a plurality of gas exhaust openings extending into the second portion. A profile of the gas exhaust openings extend into the first portion on opposing sides of the first portion.

### CROSS-REFERENCE TO RELATED APPLICATION

This application claims the benefit of U.S. provisional patent application Ser. No. 63/634,127, filed Apr. 15, 2024, which is herein incorporated by reference in its entirety.

### BACKGROUND

### Field

The present disclosure relates to liners having flow openings, and related chamber kits, processing chambers, and methods for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

However, operations (such as epitaxial deposition operations) can involve gas leakage and non-uniform flow of gases. These gas issues can cause deposition non-uniformities (such as edge roll off on processed substrates) leading to uneven distribution of deposited material.

Therefore, a need exists for improved apparatuses and methods in semiconductor processing.

### SUMMARY

The present disclosure relates to liners having flow openings, and related chamber kits, processing chambers, and methods for semiconductor manufacturing.

In one or more embodiments, a processing chamber is provided. The processing chamber includes a chamber body at least partially defining a processing volume, a substrate support disposed in the processing volume, and one or more heat sources operable to heat the processing volume. The process chamber further includes a first liner. The first liner includes a first inner face, a first outer face opposing the first inner face, a first portion defining at least part of the first outer face and the first inner face, and a second portion defining at least part of the first outer face and the first inner face, the second portion opposing the first portion, and the second portion and the first portion having an azimuthal angle greater than 150 degrees. The first liner further including a first gas inlet opening extending into the first portion, and a plurality of first gas exhaust openings extending into the second portion. A profile of the first gas exhaust openings extends into the first portion on opposing sides of the first portion.

In one or more embodiments, a liner for a processing chamber is provided. The liner includes an inner face, an outer face opposing the inner face, a first portion defining at least part of the outer face and the inner face, and a second portion defining at least part of the outer face and the inner face, the second portion opposing the first portion, and the second portion and the first portion having an azimuthal angle greater than 150 degrees. The liner further includes a gas inlet opening extending into the inner face and into the first portion, and a plurality of gas exhaust openings extending into the second portion. A profile of the gas exhaust openings extends into the first portion on opposing sides of the first portion.

In one or more embodiments, a chamber kit for a substrate processing chamber is provided. The chamber kit includes a first liner. The first liner includes a first inner face, a first outer face opposing the first inner face, a first portion, a second portion opposing the first portion, and the second portion and the first portion having an azimuthal angle greater than 150 degrees. The first liner further includes a first gas inlet opening extending into the first inner face and the first portion, and a plurality of first gas exhaust openings extending into the first inner face and the second portion. A profile of the first gas exhaust openings extends into the first portion on opposing sides of the first portion. The chamber kit further includes a second liner. The second liner includes a second inner face, and a second outer face opposing the first inner face.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2A is a schematic isometric view of a middle chamber liner shown in FIG. 1, according to one or more embodiments.

FIG. 2B is a schematic top view of the middle liner shown in FIG. 2A, according to one or more embodiments.

FIG. 2C is a schematic bottom view of the middle liner shown in FIG. 2A, according to one or more embodiments.

FIG. 3 is a schematic isometric view of a chamber kit 300 applicable for semiconductor manufacturing, according to one or more embodiments.

FIG. 4 is a schematic block diagram view of a method of substrate processing for semiconductor manufacturing, according to one or more embodiments.

FIG. 5 is a schematic top view of the middle liner shown in FIG. 2A during processing, according to one or more embodiments.

FIG. 6 is a schematic top view of a middle liner with inserts to adjust flow, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to liners having flow openings, and related chamber kits, processing chambers, and methods for semiconductor manufacturing. As an example, the disclosure can mitigate edge roll off on processed substrates. In one or more embodiments, a liner includes a plurality of exhaust openings that are sized and arranged to enhanced processing, such as to enhance uniformity and/or reduced edge roll-off.

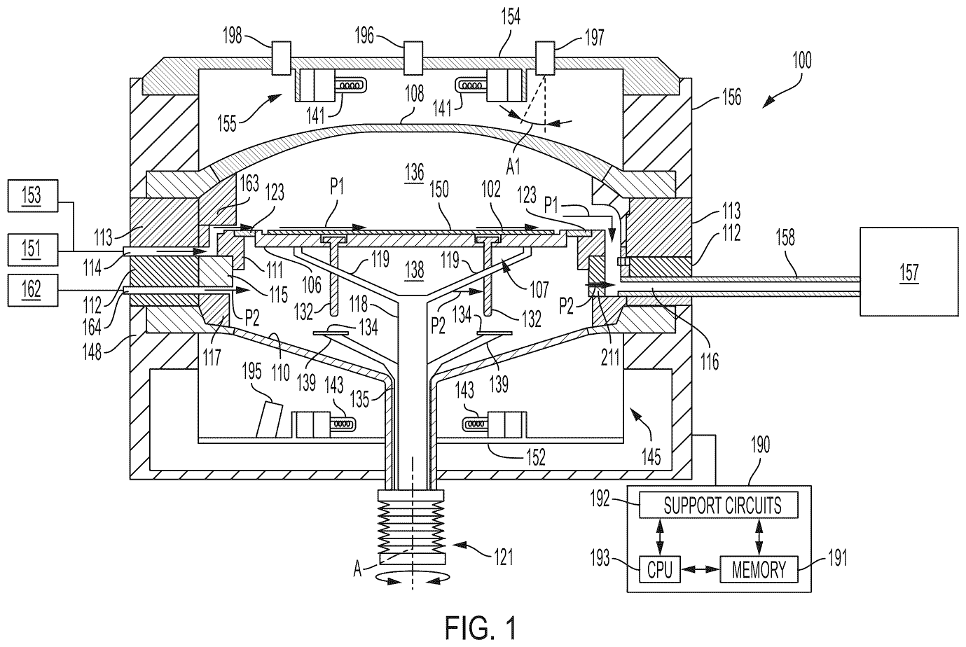

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, an upper flow module 113, and a lower flow module 112 disposed between the upper body 156 and the lower body 148. The upper body 156, the upper flow module 113, the lower flow module 112, and the lower body 148 form sidewalls of a chamber body. Disposed within the chamber body is a substrate support 106, an upper window 108 (such as an upper dome), a lower window 110 (such as a lower dome), and one or more heat sources 141, 143. The one or more heat sources 141, 143 include a plurality of upper heat sources 141 and a plurality of lower heat sources 143. In one or more embodiments, the upper heat sources 141 include upper lamps and the lower heat sources 143 include lower lamps. In one or more embodiments, the lamps include halogen lamps. In one or more embodiments, the lamps are operable to emit infrared light, heat, and/or ultraviolet light. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper window 108 and the lower window 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper window and a lid 154. The plurality of upper heat sources 141 form a portion of the upper heat source module 155.

The plurality of lower heat sources 143 are disposed between the lower window 110 and a floor 152. The plurality of lower heat sources 143 form a portion of a lower heat source module 145. The upper window 108 is an upper dome and/or is formed of an energy transmissive material, such as quartz. The lower window 110 is a lower dome and/or is formed of an energy transmissive material, such as quartz.

A processing volume 136 and a purge volume 138 are formed between the upper window 108 and the lower window 110. The processing volume 136 and the purge volume 138 are part of an internal volume defined at least partially by the upper window 108, the lower window 110, and one or more liners 163, 115, 117. In one or more embodiments, the chamber includes three liners 163, 115, 117. In one or more embodiments, an upper liner 163 (e.g., a second liner), a middle liner 115 (e.g., a first liner), and a lower liner 117 (e.g., a third liner). The one or more liners 163, 115, 117 are disposed inwardly of the upper flow module 113 and the inner flow module 112.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The upper flow module 113 and the lower flow module 112 include one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116. The one or more gas exhaust outlets 116 can be at least partially formed in one or more flow housings 158 (e.g., gas boxes). In one or more embodiments, the upper flow module 113 and the lower flow module 112 are made of a metal. In one or more embodiments, the upper flow module 113 and lower flow module 112 abut against the liners 163, 115, 117. A pre-heat ring 123 is disposed below the one or more gas inlets 114 and the one or more gas exhaust outlets 116. The pre-heat ring 123 is disposed outwardly of the substrate support 106. The pre-heat ring 123 includes a complete ring or one or more ring segments. The pre-heat ring 123 is disposed on top of a support liner 111, above the one or more purge gas inlets 164.

The one or more liners 163, 115, 117 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 parallel to the top surface 150 of a substrate 102 disposed within the processing volume 136 and one or more purge gases P2 through the purge volume 138. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to the one or more exhaust pump(s) 157. The exhaust pump 157 can assist in the controlled deposition of a layer on the substrate 102. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (CI). In one or more embodiments, the one or more process gases P1 include silicon phosphide (SiP) and/or phosphine (PH₃), and the one or more cleaning gases include hydrochloric acid (HCl).

The upper flow module 113 and the lower flow module 112 (which can be at least part of a sidewall of the processing chamber 100) include the one or more gas inlets 114 in fluid communication with the processing volume 136. The one or more gas inlets 114 are in fluid communication with one or more flow gaps between the upper liner 163 and the middle liner 115.

During a deposition operation (e.g., an epitaxial growth operation), the one or more process gases P1 flow through the one or more gas inlets 114, through the one or more gaps, and into the processing volume 136 to flow over the substrate 102.

The present disclosure contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the middle liner 115. The one or more purge gases P2 can flow through openings 211 in the middle liner 115 and join the flow of the one or more process gases P1 in the one or more gas exhaust outlets 116. The one or more process gases P1, and the one or more purge gases P2 are exhausted through the one or more gas exhaust outlets 116.

During a cleaning operation, one or more cleaning gases flow through the one or more gas inlets 114, through the one or more gaps (between the upper liner 163 and the middle liner 115), and into the processing volume 136.

The processing system includes one or more sensor devices 195, 196, 197, 198 (e.g., temperature sensors) configured to measure parameter(s) (e.g., temperature(s)) within the processing chamber 100. In one or more embodiments, the one or more temperature sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one or more embodiments, the one or more sensor devices 195, 196, 197, 198 each include a sensor that includes one or more of silicon (Si), carbon (C), gallium (Ga), and/or nitrogen (N). In one or more embodiments, the one or more sensor devices 195, 196, 197, 198 each include a silicon sensor, a silicon carbide (SiC) sensor, and/or a gallium nitride (GaN) sensor. In one or more embodiments, each sensor device 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature.

In one or more embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

Each sensor device 195, 196, 197, 198, can be a single-wavelength sensor device or a multi-wavelength (such as dual-wavelength) sensor device. In one or more embodiments, the system including the process chamber 100 includes any one, any two, or any three of the four illustrated sensor devices 195, 196, 197, 198. In one or more embodiments, the process chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198.

As shown in FIG. 1, a controller 190 is in communication with the processing chamber 100 and is used to control processes and methods, such as the operations of the methods described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, the substrate support 106, and/or the liners 163, 115, 117. As described the one or more sensor devices can include, for example pyrometers.

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a flow rate of the one or more process gases P1, a vacuum power applied using the one or more exhaust pump(s) 157, a power applied to the heat sources 141, 143, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control the deposition, the cleaning, the exhausting of gases, the rotational position, the heating, and gas flow through the processing chamber 100 by providing an output to the controls for the sensor devices 195, 196, 197, 198, the upper heat sources 141, the lower heat sources 143, the process gas source 151, the purge gas source 162, the motion assembly 121, and/or the exhaust pump(s) 157.

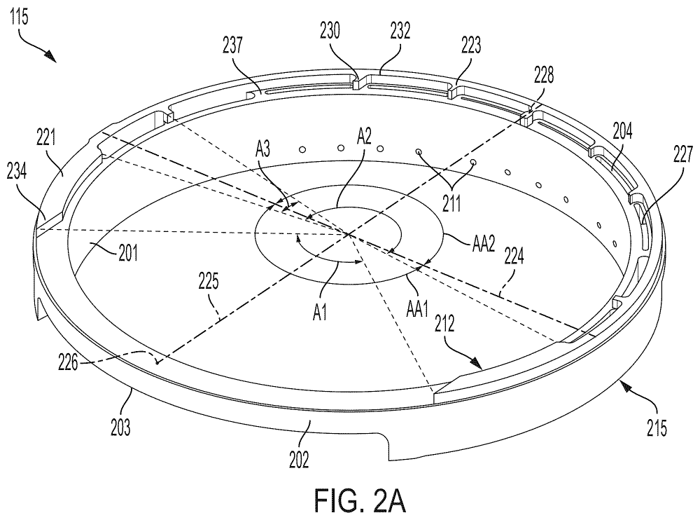

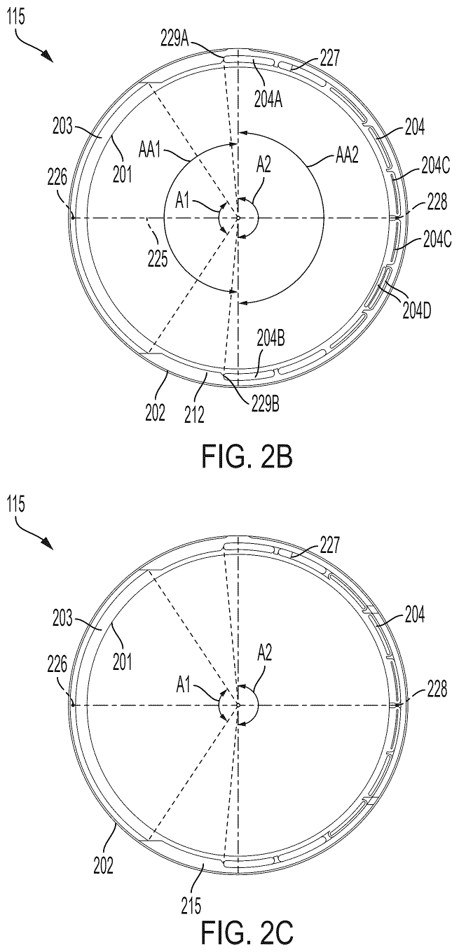

FIG. 2A is a schematic isometric view of the middle liner 115 shown in FIG. 1, according to one or more embodiments.

The middle liner 115 includes an inner face 201, an outer face 202, a gas inlet opening 203, and one or more exhaust opening(s) 204 (a plurality, e.g. ten openings, are shown). The middle liner 115 includes a first side face 212 (e.g., a top face) of the middle liner 115. The middle liner 115 includes a second side face 215 (e.g., a bottom face) opposing the first side face 212. The first side face 212 and the second side face 215 extend between the inner face 201 and the outer face 202. The middle liner 115 includes one or more lower flow openings 211 through which the one or more purge gases P2 can flow though the exhaust opening(s) 204 to the one or more exhaust outlets 116 (FIG. 1). The one or more gas exhaust openings 204 are at least part of the one or more exhaust outlets 116 shown in FIG. 1. For example, the one or more exhaust outlets 116 can respectively include a gas path defined by multiple openings in multiple components.

In one or more embodiments, the inner face 201 is curved, such as circular. The outer face 202 is also curved, such as circular. Other shapes are contemplated for the inner face 201, the outer face 202, and/or the middle liner 114. For example, linear, rectangular, and/or other shapes are contemplated. The middle liner 115 has a first portion 221 and a second portion 223. In one or more embodiments, the first portion 221 and the second portion 223 are both semicircular in shape. The first portion 221 and the second portion 223 are divided by a line 224. The first portion 221 and the second portion 223 together can define the inner face 201 and the outer face 202. The first portion 221 has an angle AA1 (e.g., an azimuthal angle). The second portion 223 has an angle AA2 (e.g., an azimuthal angle). Angle AA1 and Angle AA2 are greater than 150 degrees, such as greater than 170 degrees, such as about 180 degrees. In one or more embodiments, angle AA1 and angle AA2 are about 180 degrees. In one or more embodiments, angle AA1 and angle AA2 are equal to each other. The angles AA1, AA2 can be different from each other. The first portion 221 and the second portion 223 together can form a ring, such as a circular ring. Each portion can span 180 degrees and can split the inner face 201 and outer face 202 in half. A centerline 225 bisects both the first portion 221 and the second portion 223. The centerline 225 is perpendicular to the line 224. The centerline 225 intersects the inner face 201 at a location aligning with a center point 226 of an arc of the first portion 221 and a center point 228 of an arc of the second portion 223. The gas inlet opening 203 is centered along the centerline 225 and is centered to align with the center point 226 of the first portion 221. The gas inlet opening 203 extends from the center point 226 of the first portion 221 in both directions. The gas inlet opening 203 can extend to define an angle A1 (e.g., an azimuthal angle). Angle A1 is 15 degrees or more, such as 30 degrees or more, for example 45 degrees or more, such as 60 degrees or more, along the first portion 221. Other values are contemplated for the angle A1.

As discussed above, the present disclosure contemplates that other shapes (such as rectangular) may be used for the middle liner 115 that is shown as circular.

A profile of the one or more of gas exhaust openings 204 is centered along the centerline 225 and is centered to align with the center point 228 of the second portion 223. The profile extends between a first outer end 229A (FIG. 2B) of a first outermost exhaust opening 204A and a second outer end 229B (FIG. 2B) of a second outermost exhaust opening 204B. The gas exhaust openings 204 extend from the center point 228 of the second portion 223 in both directions. The plurality of gas exhaust openings 204 extend from the second portion 223 and into the first portion 221. The plurality of gas exhaust openings 204 extend along the inner face 201 and can be positioned to define an angle A2 (e.g., an azimuthal angle). Angle A2 is about 181 degrees to about 210 degrees, such as about 190 degrees to about 205 degrees. In one or more embodiments, the angle A2 is about 190 degrees. In one or more embodiments, the angle A2 is about 203 degrees. Other values are contemplated for the angle A2. Angle A2 can be defined as the angle from the first outer end 229A of the first outermost exhaust opening 204A on one side of the centerline 225 to the second outer end 229B of the second outermost exhaust opening 204B on the other side of the centerline 225. Each exhaust opening 204 extends at an angle A3 from a first end to a second end of the respective exhaust opening 204. The angle A3 of each exhaust opening 204 extends along the inner face 201 about 7 degrees to about 30 degrees, such as about 12 degrees, to about 18 degrees, such as about 14 degrees to about 17 degrees. Angle A2 can be defined as the summation of the angles A3 for each exhaust opening 204 in addition to angle(s) of the spacing(s) between each exhaust opening 204. In one or more embodiments, the one or more gas exhaust openings 204 includes greater than 6 gas exhaust openings, such as greater than 8 gas exhaust openings. In one or more embodiments, the one or more gas exhaust openings 204 include at least 8 gas exhaust openings, such as at least 10 gas exhaust openings. In one or more embodiments, the one or more gas exhaust openings 204 include at least 12 gas exhaust openings.

At least one (such as each) of the one or more of gas exhaust openings 204 has a width 227. The width 227 can be defined by a difference between an outer radius and an inner radius of the respective exhaust opening. The width 227 ranges from about 0.5 mm to 20 mm, such as about 1 mm to about 18 mm, for example about 1 mm to about 10 mm. In one or more embodiments, the width 227 varies across at least one of the gas exhaust openings 204. In one or more embodiments, one or more center exhaust openings 204C (FIG. 2B) have a smaller width than edge gas exhaust openings (e.g., 204A and 204B marked in FIG. 2B) that are positioned on the outside of the plurality of gas exhaust openings 204. A cross-sectional area of each exhaust opening 204 may be determined using the width 227, the angle A3, and a circumference of the middle liner 115. Other methods of determining the cross-sectional area are contemplated. The cross-section area of each exhaust opening 204 may be about 25 mm² to about 1000 mm², such as 40 mm² to about 700 mm², such as 50 mm² to about 610 mm².

The width 227 may increase (e.g., in a gradient) from the innermost exhaust opening(s) (e.g., 204C) to the outermost exhaust opening(s) (e.g., 204A, 204B) of the plurality of gas exhaust openings 204 on both sides of the innermost exhaust opening. For example, the innermost exhaust opening(s) (e.g., innermost relative to the centerline 225, such as 204C) may have a width 227 of about 0.5 mm to about 5 mm, such as about 1 mm to about 3 mm, such as about 1 mm. As another example, the outermost gas exhaust opening(s) (e.g., outermost relative to the centerline 225, such as outermost gas exhaust openings 204A, 204B) may have a width 227 of about 6 mm to about 11 mm, such as about 8 mm to about 10 mm, such as about 9 mm. The gradient of the width 227 may increase the width 227 over each exhaust opening 204, every two gas exhaust openings 204, every four gas exhaust openings, or a combination thereof. A ratio of the gradient (e.g., the ratio by which the width 227 increases) from smallest to largest may be about 1:4 to about 1:25, such as about 1:7 to about 1:13, such as about 1:9.

In one or more embodiments, the cross-sectional area of the gas exhaust openings 204 increases (e.g., in a gradient) from the innermost exhaust opening(s) (e.g., 204C) to the outermost exhaust opening(s) (e.g., 204A, 204B) of the plurality of gas exhaust openings 204 on both sides of the innermost exhaust opening(s). For example, the innermost exhaust opening(s) (e.g., innermost relative to the centerline 225, such as 204C) may have a cross-sectional area of about 40 mm² to about 70 mm², such as about 50 mm² to about 60 mm², such as about 53 mm². As another example, the outermost gas exhaust openings(s) (e.g., outermost relative to the centerline 225, e.g. 204A, 204B) may have a cross-sectional area of about 500 mm² to about 700 mm², such as about 550 mm² to about 650 mm², such as about 602 mm². The gradient of the cross-sectional area may increase the cross-sectional area over each exhaust opening 204, every two gas exhaust openings 204, every four gas exhaust openings, or a combination thereof. A ratio of the gradient (e.g., the ratio by which the cross-sectional area increases) from smallest to largest may be about 1:4 to about 1:25, such as about 1:8 to about 1:14, such as about 1:11.3.

The gas exhaust openings 204 are disposed along a plurality of regions including an innermost region (e.g., innermost relative to the centerline 225) and an outermost region (e.g., outermost relative to the centerline 225). The regions are arranged azimuthally relative to a center of the middle liner 115. A cross-sectional area of an innermost region of one or more exhaust openings 204 is less than a cross-sectional area of an outermost region of one or more exhaust openings 204. The cross-sectional area increases from the innermost region to the outermost region. The increasing cross-sectional area of the regions can be established, for example, by an increasing cross-sectional area (e.g., an increasing size) of the one or more gas exhaust openings 204 in the respective regions (as shown in FIG. 2A). As another example, the increasing cross-sectional area of the regions can be established by an increasing number of gas exhaust opening(s) 204 in the respective regions. For example, the increasing cross-sectional area of the regions can be established by using an increasing number of gas exhaust opening(s) 204 that have the same cross-sectional area (e.g., size). For example, in regions having a higher cross-sectional area a plurality of gas exhaust openings 204 can be disposed at the same azimuthal region and can be radially spaced from each other relative to the center of the middle liner 115 (as shown for visual exemplary purposes with two intermediate gas exhaust openings 204D at an azimuthal region in FIG. 2B).

In one or more embodiments, angle A3 of the gas exhaust openings 204 increases (e.g., in a gradient) from the innermost exhaust opening(s) (e.g., 204C) to the outermost exhaust opening(s) (e.g., 204A, 204B) of the plurality of gas exhaust openings 204 on both sides of the innermost exhaust opening. For example, the inner most exhaust opening(s) (e.g., innermost relative to the centerline 225, such as 204C) may have the angle A3 of about 13 degrees to about 15 degrees, such as about 14 degrees to about 15 degrees, such as about 14 degrees. As another example, the outer most gas exhaust openings(s) (e.g., outermost relative to the centerline 225m such as gas exhaust openings 204A, 204B) may have the angle A3 of about 15 degrees to about 17 degrees, such as about 16 degrees to about 17 degrees, such as about 16 degrees. Other values are contemplated for the angle A3. The gradient of the angle A3 may increase the cross-sectional area over each exhaust opening 204, every two gas exhaust openings 204, every four gas exhaust openings, or a combination thereof. A ratio of the gradient (e.g., a ratio by which the angle A3 increases) from smallest to largest may be about 1:1 to about 1:5, such as about 1:1.01 to about 1:2, such as about 1:1.143. As an example for visual exemplary purposes, the outermost gas exhaust openings 204A, 204B (FIG. 2B) have a larger angle A3 than the innermost gas exhaust openings 204C (FIG. 2B).

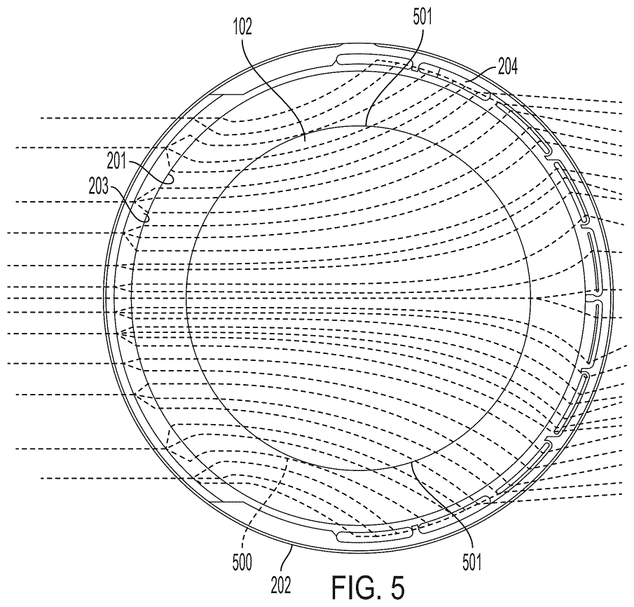

The gas exhaust openings 204 described above cause the process gases P1 to have a more equal distribution of flow over the substrate 102. As an example, curved flow profiles of gas to the gas exhaust openings 204 can be more parallel with respect to each other. By having the gas exhaust openings 204 extend into the first portion 221 of the inner face 201, the process gases P1 flow over periphery zones of the substrate 102, increasing the angular coverage of the process gases P1. The periphery zones of the substrate 102 are described in FIG. 5. Exhausting more of the process gases P1 out of the gas exhaust openings 204 farther away from the centerline 225 can lead to the more equal distribution (e.g. parallel flow of curved flow profiles) across the substrate 102. The process gases P1 flow could otherwise be concentrated near the centerline 225. By increasing the flow of process gases P1 to the edges of the substrate 102, the edge roll off the substrate 102 is reduced. For example, purge gases P2 that leak toward the edge of the substrate 102 near the outermost gas exhaust openings 204A, 204B can be biased by the process gas P1 flow into the gas exhaust openings 204. The process gases P1 flowing over the edge of the substrate 102 can facilitate evacuating the leaked purge gases P2 to the gas exhaust openings 204. Varying the width 227 of the gas exhaust openings 204, such as increasing the width 227 of the outer gas exhaust openings relative to the inner gas exhaust openings 204, can adjust the process gases P1 flow over the periphery zones of the substrate 102. The process gases P1 flowing to the periphery zones of the substrate 102 reduced or prevents purge gases P2 from seeping from below the substrate support 106 (e.g., the susceptor) to the top surface 150 and edges of the substrate 102. When the purge gases P2 are present above the substrate 102, the purge gases P2 interfere with deposition of material on the substrate 102 (e.g., by diluting the process gases P1). Dilution of the process gases P1 may cause edge roll-off on the substrate 102. The layout of the gas exhaust openings 204 allow for purge gases P2 to be flowed under the substrate support 106 to avoid deposition on the substrate support 106 while keeping the purge gases P2 away from the top surface 150 of the substrate 102 to mitigate edge roll off. Purge gases P2 that leak above the top surface 150 of the substrate 102 can be evacuated quickly away to the gas exhaust openings 204 due to the layout of the gas exhaust openings 204.

A ledge 232 may extend from a recessed surface 237 along the first side face 212. The ledge 232 is behind the plurality of gas exhaust openings 204. Notches 230 may extend from the first side face 212 between the gas exhaust openings 204. The ledge 232 and the notches 230 may assist gas flow through the gas exhaust openings 204. An edge 234 separates the gas inlet opening 203 from the plurality of gas exhaust openings 204. The edge 234 and the ledge 232 connect the middle liner 115 to the top liner 163. The gas exhaust openings 204 can extend into the recessed surface 237.

FIG. 2B is a schematic top view of the middle liner 115 shown in FIG. 2A, according to one or more embodiments. The top view shows the plurality of gas exhaust openings 204. The width, amount, and angle of the gas exhaust openings 204 are illustrated.

FIG. 2C is a schematic bottom view of the middle liner 115 shown in FIG. 2A, according to one or more embodiments. The bottom view shows the plurality of gas exhaust openings 204. The width, amount, and angle of the gas exhaust openings 204 are illustrated.

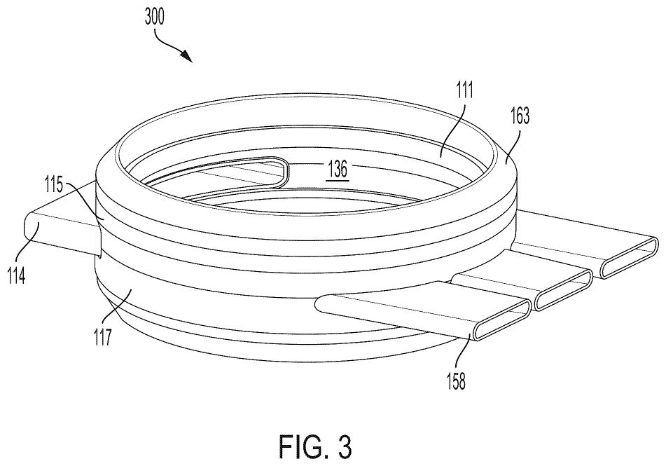

FIG. 3 is a schematic isometric view of a chamber kit 300 applicable for semiconductor manufacturing, according to one or more embodiments. The chamber kit 300 includes one or more aspects, features components, operations, and/or properties of the processing chamber 100 shown in FIGS. 1 and 2A-2C. The chamber kit 300 includes the top liner 163 e.g. second liner, the middle liner 115 e.g., first liner, and the bottom liner 117 e.g., third liner as shown in FIG. 1. In one or more embodiments, the liners 163, 115, 117 are formed from an opaque material such as silicon carbide (SiC), opaque quartz (e.g., black quartz, white quartz, and/or grey quartz), and/or graphite coated with silicon carbide and/or opaque quartz. In one or more embodiments, the liners 163, 115, 117 are formed from a transparent material such as transparent quartz. At least part of the three liners 163, 115, 117 can define at least part of the processing volume 136. The substrate 102 is disposed in the processing volume 136 on the substrate support 106 during processing (as shown in FIG. 1). The support liner 111 is disposed inside the processing volume 136 and the pre-heat ring 123 (FIG. 1) is disposed on top of a support liner 111. The middle liner 115 includes the gas exhaust openings 204 as described in FIG. 2A. The gas exhaust openings 204 fluidly connect to the flow housings 158. The chamber kit 300 includes one or more flow housings 158. In one or more embodiments, the chamber kit 300 includes three flow housings 158. The flow housings 158 are connected to the exhaust pump 157 (FIG. 1). During a deposition operation (e.g., an epitaxial growth operation), the one or more process gases P1 flow through the one or more gas inlets 114, through the gas inlet opening 203, and into the processing volume 136 to flow over the substrate 102. The process gases P1 then flow through the exhaust outlets 204 to the flow housings 158 and out of the processing chamber 100.

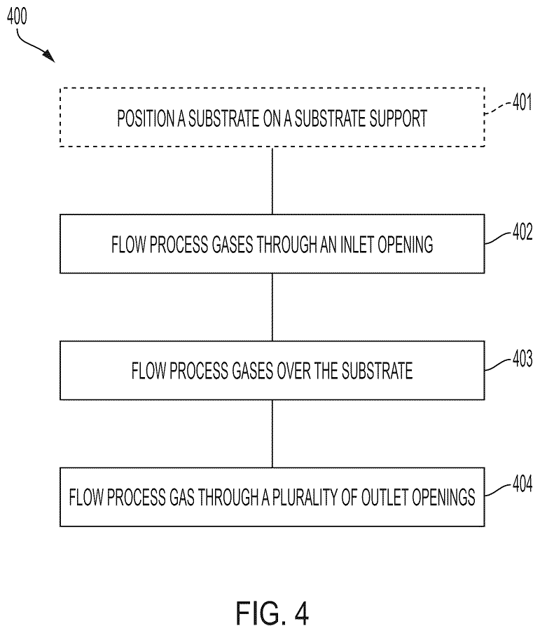

FIG. 4 is a schematic block diagram view of a method 400 of substrate processing for semiconductor manufacturing, according to one or more embodiments.

At optional operation 401, a substrate 102 is positioned on a substrate support 106. The substrate support 106 is in the processing volume 136 of a processing chamber 100. In one or more embodiments, the positioning includes moving a substrate support 106 and/or a plurality of lift pins 132 relative to each other to land the substrate 102 on the substrate support 106. The substrate support 106 is positioned such that process gases P1, flowing through the gas inlet opening 203 of the middle liner 115, will flow over the top surface 150 of the substrate 102. The position of the substrate support 106 allows for purge gases P2 to flow from the gas inlet opening 203, around the substrate support 106, and to the lower flow openings 211.

At operation 402, process gases P1 are flowed from the gas inlet opening 203 towards the substrate 102. The process gases P1 are flowed from one or more process gas sources 151 through the gas inlet(s) 114. The process gases P1 are flowed through the gas inlet opening 203 of the middle liner 115. Passing through the middle liner 115, the process gases P1 flow over the pre-heat ring 123 towards the substrate 102. During operation 402, purge gases P2 are flowed from the purge gas sources 162 to openings formed in the lower liner 117 and/or between the middle liner 115 and the lower liner 117. The purge gases P2 are flowed below and around the substrate support 106 in the purge volume 138. The controller 190 controls the amount of process gases P1 flowed from the gas inlet(s) 114 and the amount of purge gases P2 flowed from the one or more purge gas sources 162.

At operation 403, the one or more process gases P1 are flowed over the substrate 102. The process gases P1 flowing over the substrate 102 deposits material on the top surface 150 of the substrate 102. The flow direction of the process gases P1 can control (e.g., adjust) the deposition of material on the top surface 150 of the substrate 102. The flow of the process gases P1 over the substrate 102 is discussed further in FIG. 5.

At operation 404, the process gases P1 are flowed out of the plurality of gas exhaust openings 204. The process gases P1 enter the gas exhaust openings 204 after flowing over the substrate 102. The process gases P1 flow through the gas exhaust openings 204 out of the processing chamber 100. The process gases P1 are flowed through the gas exhaust openings 204 to the flow housings 158 assisted by the exhaust pump 157. The exhaust pump 157 controls the flow of the process gases P1 and purge gases P2. The purge gases P2 flow through the one or more lower flow openings 211 to the gas exhaust openings 204. The purge gases P2 then flow into the flow housings 158. The process gases P1 and purge gases P2 exit the processing chamber 100 through the flow housings 158. The controller 190 via the exhaust pump controls the rate of the process gases P1 flow through the gas exhaust openings 204. The controller 190 via the exhaust pump controls the rate of the purge gases P2 flow through the lower flow opening 211.

FIG. 5 is a schematic top view of the middle liner 115 shown in FIG. 2A during operation 403, according to one or more embodiments. The process gases P1 are shown in curved flow lines 500. The process gases P1 are flowed from the gas inlet opening 203, over the substrate 102. The gas exhaust openings 204 are positioned to cause the process gases P1 to flow more evenly over the substrate 102 such that the curved flow lines 500 are more parallel to each other. As shown in FIG. 2A-2C, the gas exhaust openings 204 extend into the first portion 221 of the middle liner 115. Both the addition of more gas exhaust openings 204 and the gas exhaust openings 204 extending to increase the angle A2, causes the process gases P1 to flow more over periphery zones 501 of the substrate 102. The periphery zones 501 of the substrate 102 include sections of the substrate 102 on opposite sides of the centerline 225. The periphery zones 501 can extend from the edges of the substrate 102. Without certain outer gas exhaust openings 204, the process gases P1 can flow primarily straight across the substrate 102, causing less deposition on the periphery zones 501 of the substrate 102 and/or increased dilution of the process P1 by the purge gases P2. The additional gas exhaust openings 204 modify the flow of the process gases P1, increasing the flow of process gases P1 over the periphery zone 501 of the substrate 102. The modified flow decreases the difference between a deposition thickness on the periphery zones 501 of the substrate 102 and the rest of the substrate 102. Decreasing the difference between a deposition thickness reduces the edge roll off on the substrate 102 as the periphery zones 501 are positioned on the edges on the substrate 102.

The modification of the flow of the process gases P1 reduces the dilution over the periphery zones 501 of the substrate 102 caused by purge gases P2. While the process gases P1 are flowing over the top surface 150 of the substrate 102, the purge gases P2 are flowing over and around the susceptor in the purge volume 138. The purge gases P2 can enter the processing volume 136 in a gap between the substrate 102 and the pre-heat ring 123. The purge gases P2 can dilute the process gases P1. Dilution of the process gas P1 over the periphery zones 501 of the substrate can exist and/or worsen without certain gas exhaust openings 204 near the periphery zones 501. With the gas exhaust openings 204, the flow of the process gases P1 moves the purge gases P2 that reach the processing volume 136 away from the top surface 150 and outer edge(s) of the substrate 102. The moving of the purge gases P2 away from the substrate 102 using the processing gases P1 allows for the purge gases P2 to flow under the substrate support 106 while not reducing or preventing dilution of the processing gases P1.

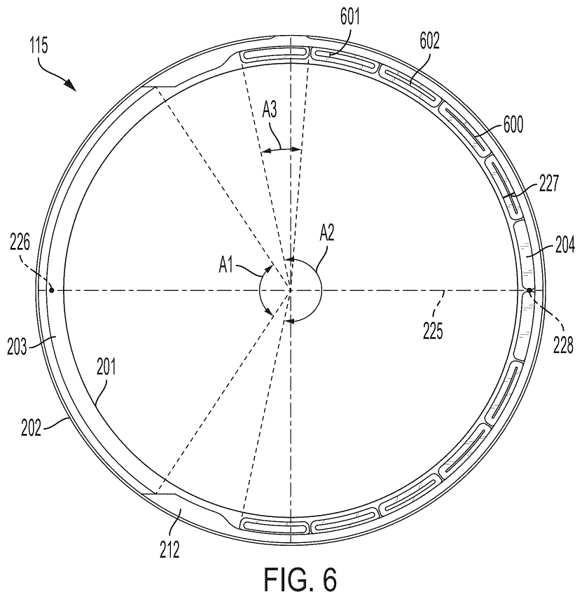

FIG. 6 is a schematic top view of the middle liner 115 with inserts 600 to adjust (e.g., optimize) flow, according to one or more embodiments. The middle liner 115 is shown in FIG. 2A. In one or more embodiments, the middle liner 115 has a constant width 227 for each gas exhaust openings 204. The inserts 600 are used to adjust the width 227 of the gas exhaust openings 204. The inserts 600 respectively include an insert opening 602 that have a width 601. The inserts 600 are inserted into the exhaust opening 204 to adjust the size and/or shape of the exhaust opening 204 to the insert opening 602. The inserts 600 may be inserted into gas exhaust openings 204 to retrofit the middle liner 115. The inserts 600 can be used in gas exhaust openings 204 having the same size to establish insert openings 602 (used for exhausting gas) that have differing sizes (for example, the gradient described above). At least one insert 600 can omit the insert opening 602 such that the at least one insert 600 closes off at least one exhaust opening 204. The inserts may be inserted into gas exhaust openings 204 to modify the gas exhaust openings 204 in response to changing processing conditions.

Benefits of the present disclosure include enhanced deposition uniformity and modifying the flow of process gases to reduce edge roll off on substrates. The disclosure also includes reduced or eliminated process gas dilution, and moving purge gases away from the top surface and edges of the substrate while letting the purge gas contact the substrate support to reduce backside deposition. The disclosure allows for decreasing the difference in deposition thickness across the substrate by achieving more parallel flow over the substrate and increasing angular coverage on the edges of the substrate.

It is contemplated that one or more aspects disclosed herein may be combined. As an example, one or more aspects, features, components, operations and/or properties of the processing chamber 100; the upper liner 163; the middle liner 115; the lower liner 117; the upper flow module 113; the lower flow module 112; the gas inlet 114; the purge inlet 164; the exhaust outlet 116; the flow housings 158; the gas inlet opening 203; the exhaust opening(s) 204; the method 400; and/or insert(s) 600 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
a chamber body at least partially defining a processing volume;
a substrate support disposed in the processing volume;
one or more heat sources operable to heat the processing volume; and
the chamber body comprising a first liner, the first liner comprising:
a first inner face
a first outer face opposing the first inner face;
a first portion defining at least part of the first outer face and the first inner face;
a second portion defining at least part of the first outer face and the first inner face, the second portion opposing the first portion, and the second portion and the first portion having an azimuthal angle greater than 150 degrees;
a first gas inlet opening extending into the first portion; and
a plurality of first gas exhaust openings extending into the second portion, a profile of the first gas exhaust openings extending into the first portion on opposing sides of the first portion.

2. The processing chamber of claim 1, wherein the processing chamber further comprises:
a second liner at least partially supporting the first liner, the second liner comprising:
a second inner face; and
a second outer face opposing the second inner face.

3. The processing chamber of claim 2, wherein the processing chamber further comprises one or more flow housings fluidly connected to the plurality of first gas exhaust openings.

4. The processing chamber of claim 2, wherein the processing chamber further comprises a pre-heat ring disposed outwardly of the substrate support.

5. The processing chamber of claim 3, wherein the processing chamber further comprises:
a gas inlet fluidly connected to the first gas inlet opening; and
a gas exhaust fluidly connected to the one or more flow housings.

6. The processing chamber of claim 1, wherein the plurality of first gas exhaust openings are disposed along a plurality of regions, wherein a cross-sectional area of an innermost region of one or more exhaust openings is less than a cross-sectional area of an outermost region of one or more exhaust openings, wherein the cross-sectional area increases from the innermost region to the outermost region.

7. The processing chamber of claim 1, wherein the first gas inlet opening extends to define an angle of at least 45 degrees.

8. The processing chamber of claim 1, further comprising an insert disposed in at least one of the plurality of first gas exhaust openings to modify a width of the at least one of the first gas exhaust openings.

9. A liner for a processing chamber, comprising:
an inner face
an outer face opposing the inner face;
a first portion defining at least part of the outer face and the inner face;
a second portion defining at least part of the outer face and the inner face, the second portion opposing the first portion, and the second portion and the first portion having an azimuthal angle greater than 150 degrees;
an gas inlet opening extending into the inner face and into the first portion; and
a plurality of gas exhaust openings extending into the second portion, a profile of the gas exhaust openings extending into the first portion on opposing sides of the first portion.

10. The liner of claim 9, wherein the liner further comprises:
a first side face extending between the inner face and the outer face; and
a second side face extending between the inner face and the outer face, the second side face opposing the first side face,
wherein the gas inlet opening, and the plurality of gas exhaust openings extend into the second side face.

11. The liner of claim 9, wherein the profile of the plurality of gas exhaust openings extends to define an angle of about 190 degrees to about 205 degrees.

12. The liner of claim 9, wherein the plurality of gas exhaust openings comprise at least 10 gas exhaust openings.

13. The liner of claim 9, wherein a width of the plurality of gas exhaust openings varies across at least one of the gas exhaust openings.

14. The liner of claim 9, wherein each of the plurality of the gas exhaust openings has a width, and the width of an innermost exhaust opening is less than the width of an outermost exhaust opening, wherein the width increases from the innermost exhaust opening to the outermost exhaust opening.

15. The liner of claim 9, wherein the gas inlet opening extends to define an angle of at least 45 degrees.

16. The liner of claim 9, further comprising an insert disposed in at least one of the plurality of gas exhaust openings to modify a width of the at least one of the gas exhaust openings.

17. A chamber kit for a substrate processing chamber, comprising:
a first liner comprising:
a first inner face
a first outer face opposing the first inner face;
a first portion;
a second portion opposing the first portion, the second portion and the first portion having an azimuthal angle greater than 150 degrees;
a first gas inlet opening extending into the first inner face and the first portion; and
a plurality of first gas exhaust openings extending into the first inner face and the second portion, a profile of the first gas exhaust openings extending into the first portion on opposing sides of the first portion; and
a second liner comprising:
a second inner face; and
a second outer face opposing the first inner face.

18. The chamber kit for a substrate processing chamber of claim 17, wherein the profile of the plurality of first gas exhaust openings extends to define an angle of at least 203 degrees.

19. The chamber kit for a substrate processing chamber of claim 17, wherein the plurality of first gas exhaust openings comprises at least 10 gas exhaust openings.

20. The chamber kit for a substrate processing chamber of claim 17, wherein a width of the plurality of first gas exhaust openings varies across at least one of the first gas exhaust openings.
